(19) United States
(12) Patent Application Publication
(10) Pub. No.: US 2011/0221481 A1
(43) Pub. Date: Sep. 15, 2011

(54) GATE DRIVE CIRCUIT

(75) Inventor: Takayuki KIFUKU, Chiyoda-ku (JP)

(73) Assignee: MITSUBISHI ELECTRIC CORPORATION, Tokyo (JP)

(21) Appl. No.: 12/886,096

(22) Filed: Sep. 20, 2010

(30) Foreign Application Priority Data
Mar. 9, 2010 (JP) 2010-051813

(51) Int. Cl. H03K 3/00

(52) U.S. Cl. 327/109

(57) ABSTRACT

Provided is a gate drive circuit capable of turning off a MOS-FET reliably without adding a complicated structure. The gate drive circuit for driving a power MOS-FET includes: a first switching element connected to a gate terminal of the power MOS-FET through a first resistor, for setting a gate potential of the power MOS-FET to a potential for turning on the power MOS-FET, based on a signal from a signal source; and a second switching element connected to the gate terminal of the power MOS-FET through a second resistor, for setting the gate potential of the power MOS-FET to a potential for turning off the power MOS-FET, based on the signal from the signal source, in which the first resistor has a resistance value set to a value larger than a resistance value of the second resistor.

### BACKGROUND OF THE INVENTION

1. Field of the Invention

The present invention relates to a gate drive circuit for driving a power MOS-FET.

2. Description of the Related Art

A so-called totem-pole type circuit in which a plurality of N-channel MOS-FETs (power MOS-FETs) are connected in series and connection points between the N-channel MOS-FETs are connected to an electrical load has been generally known as a drive circuit for driving the electrical load, for example, a motor. The drive circuit for driving the electrical load is used with, for example, a half bridge, an H-bridge, or a multi-phase bridge, and has various applications.

For example, in an electric power steering apparatus for vehicle, as illustrated in FIG. 4, a drive circuit for driving a motor by an H-bridge circuit including four N-channel MOS-FETs has been generally known.

In FIG. 4, output terminals of an H-bridge circuit 1 including N-channel MOS-FETs 10a, 10b, 10c, and 10d are connected to a motor M to couple between the output terminals (to bridge between output terminals). A battery 2 is connected between input terminals of the H-bridge circuit 1. Gate terminals of the four N-channel MOS-FETs 10a to 10d are connected to gate drive circuits 3a, 3b, 3c, and 3d through gate resistors Rga, Rgb, Rgc, and Rgd, respectively. The gate drive circuits 3a to 3d are connected to signal sources 4a, 4b, 4c, and 4d, respectively, to allow the gate drive circuits 3a to 3d to separately operate.

A control unit including a microcomputer (not shown) computes a desired target torque based on results obtained by detection by various sensors (not shown) such as a steering torque sensor which is provided in a vehicle steering system (not shown) for detecting the steering power of a driver and a vehicle speed sensor for detecting a vehicle speed.

The signal sources 4a to 4d output signals for driving the four N-channel MOS-FETs 10a to 10d to generate the desired target torque computed by the control unit in the motor M. Motor terminal voltage detection circuits 5a and 5b are provided at the respective output terminals of the H-bridge circuit 1 to detect terminal voltages of the output terminals, that is, motor terminal voltages.

The gate drive circuit 3a has a structure in which a PNP transistor Q1a and an NPN transistor Q2a are connected in series. A connection point between the PNP transistor Q1a and the NPN transistor Q2a is connected to the gate terminal of the N-channel MOS-FET 10a through the gate resistor Rga. The PNP transistor Q1a and the NPN transistor Q2a are complementarily turned on and off in response to a signal from the signal source 4a.

When the PNP transistor Q1a is turned on, a voltage for turning on the N-channel MOS-FET 10a is applied to the gate terminal of the N-channel MOS-FET 10a. When the NPN transistor Q2a is turned on, a voltage for turning off the N-channel MOS-FET 10a is applied to the gate terminal of the N-channel MOS-FET 10a. The structure and operation of each of the gate drive circuits 3b to 3d are the same as the gate drive circuit 3a, and hence the detailed description thereof is omitted here. For example, when the motor M is rotated in the right direction, the N-channel MOS-FETs 10a and 10d are turned on. For example, when the motor M is rotated in the left direction, the N-channel MOS-FETs 10b and 10c are turned on.

An operation particularly in a case where the high-potential side N-channel MOS-FET 10a is turned off in the circuit for driving the N-channel MOS-FETs which are totem-pole-connected as described above is studied in detail.

When the NPN transistor Q2a is turned on to turn off the high-potential side N-channel MOS-FET 10a, a gate potential of the high-potential side N-channel MOS-FET 10a reduces to a ground potential. With the reduction in gate potential, a gate-source voltage of the high-potential side N-channel MOS-FET 10a reduces, and hence the high-potential side N-channel MOS-FET 10a becomes an off state.

In this case, a current flowing through the motor M continues to flow therethrough because of an inductance component of the motor M. Therefore, a current (so called regenerative current) starts to flow through a parasitic diode formed with the low-potential side N-channel MOS-FET 10c connected in series to the high-potential side N-channel MOS-FET 10a. The regenerative current causes the voltage drop of the parasitic diode with the low-potential side N-channel MOS-FET 10c. Thus, a potential of a connection point between the high-potential side N-channel MOS-FET 10a and the low-potential side N-channel MOS-FET 10c is lower than the ground potential by the voltage drop of the parasitic diode (approximately 0.7 V in general case), and hence the potential becomes negative.

Then, the gate-source voltage of the high-potential side N-channel MOS-FET 10a increases, and hence the high-potential side N-channel MOS-FET 10a cannot be completely turned off. When a subsequent operation is performed, the low-potential side N-channel MOS-FET 10c is turned on, and hence a problem may occur that both the high-potential side N-channel MOS-FET 10a and the low-potential side N-channel MOS-FET 10c are turned on and thus a short-circuit current flows.

As illustrated in FIG. 5, it has been known that an N-channel MOS-FET includes a capacitor component called an input capacitor inherent in the structure. An input capacitor C and a gate resistor Rg connected to the gate terminal of the N-channel MOS-FET serve as a so-called integrating circuit. Therefore, when a rectangular-shaped gate signal is applied to the N-channel MOS-FET, a period up to the time when a gate-source potential difference becomes a potential difference for turning on the N-channel MOS-FET and a period up to the time when the gate-source potential difference becomes a potential difference for turning off the N-channel MOS-FET (that is, switching speed) are determined based on a value of the gate resistor Rg.

In order to prevent the short-circuit current described above, it is important to reduce the gate resistance to shorten the period up to the time when the gate-source potential difference becomes the potential difference for turning off the N-channel MOS-FET. When the gate resistance reduces, the switching speed increases, but electromagnetic noise occurs when the N-channel MOS-FET is turned on.

That is, when the N-channel MOS-FET is to be turned off, the gate terminal of the N-channel MOS-FET is connected to the ground side (ground potential) of the power supply through the gate resistor and the NPN transistor. However, in order to prevent the noise described above, it is also necessary to set the gate resistance to a relatively large resistance value. In contrast, in order to prevent the short-circuit current, it is necessary to set the gate resistance to a relatively small resistance value. Therefore, a problem may occur that compatibility therebetween is difficult.

A known method for solving the problem that the high-potential side N-channel MOS-FET cannot be completely turned off is disclosed in Japanese Patent Application Laid-open No. Hei 02-87963.

Hereinafter, an operation of a gate drive circuit of a motor drive circuit disclosed in Japanese Patent Application Laid-open No. Hei 02-87963 is described. The description is given with reference to FIG. 6, which is a diagram schematically illustrating only a related part of Japanese Patent Application Laid-open No. Hei 02-87963 (in particular, FIG. 3). In FIG. 6, the same reference symbols as those in FIG. 4 indicate the same portions, and thus the detailed description thereof is omitted. The circuit structure of the motor drive circuit illustrated in FIG. 6 is different from the circuit structure of the motor drive circuit illustrated in FIG. 4 in the point that emitters of the NPN transistors Q2a and Q2b of the gate drive circuits 3a and 3b are connected to negative power supplies 6a and 6b, respectively.

In the gate drive circuits illustrated in FIG. 6, particularly when the high-potential side N-channel MOS-FET 10a is to be turned off, the NPN transistor Q2a is turned on. Then, the gate terminal of the high-potential side N-channel MOS-FET 10a is connected to the negative power supply 6a through the gate resistor Rga to reduce the gate potential of the high-potential side N-channel MOS-FET 10a, to thereby turn off the high-potential side N-channel MOS-FET 10a.

In the gate drive circuit illustrated in FIG. 6, even when the regenerative current flows through the gate drive circuit and the potential of the connection point between the high-potential side N-channel MOS-FET 10a and the low-potential side N-channel MOS-FET 10c which are totem-pole-connected is reduced by the voltage drop of the parasitic diode with the low-potential side N-channel MOS-FET 10c and thus becomes negative, the gate-source voltage of the high-potential side N-channel MOS-FET 10a may be sufficiently reduced. As a result, the high-potential side N-channel MOS-FET 10a may be completely turned off.

Next, an operation of a gate drive circuit of a motor drive circuit disclosed in Japanese Patent Application Laid-open No. 2004-328413 is described. The description is given with reference to FIG. 7, which is a diagram schematically illustrating only a related part of Japanese Patent Application Laid-open No. 2004-328413 (in particular, FIG. 1). In FIG. 7, the same reference symbols as those in FIGS. 4 and 6 indicate the same portions, and thus the detailed description thereof is omitted. The circuit structure of the motor drive circuit illustrated in FIG. 7 is different from the circuit structure of the motor drive circuit illustrated in FIG. 4 in the point that the emitters of the NPN transistors Q2a and Q2b of the gate drive circuits 3a and 3b are connected to sources of the high-potential side N-channel MOS-FETs 10a and 10b, respectively.

In the gate drive circuits illustrated in FIG. 7, particularly when the high-potential side N-channel MOS-FET 10a is to be turned off, the PNP transistor Q2a is turned on. Then, the gate terminal of the high-potential side N-channel MOS-FET 10a is connected to a source terminal of the high-potential side N-channel MOS-FET 10a through the gate resistor Rga.

Therefore, even when the regenerative current flows through the gate drive circuit and the potential of the connection point between the high-potential side N-channel MOS-FET 10a and the low-potential side N-channel MOS-FET 10c which are totem-pole-connected is reduced by the voltage drop of the parasitic diode with the low-potential side N-channel MOS-FET 10c and thus becomes negative, the potentials of the gate terminal and the source terminal of the high-potential side N-channel MOS-FET 10a are the same. Thus, the high-potential side N-channel MOS-FET 10a may be sufficiently reduced. As a result, the high-potential side N-channel MOS-FET 10a may be completely turned off.

As described above, the gate drive circuits disclosed in Japanese Patent Application Laid-open Nos. Hei 02-87963 and 2004-328413 may solve the problem on the general gate drive circuit as illustrated in FIG. 4. However, there arise the following other problems.

First, the gate drive circuit as disclosed in Japanese Patent Application Laid-open No. Hei 02-87963 (gate drive circuit as schematically illustrated in FIG. 6) requires the negative power supplies 6a and 6b. When a single power supply (vehicle-mounted battery in a case of electric power steering apparatus) is used as in the case of the above-mentioned electric power steering apparatus for vehicle, it is necessary for the negative power supplies 6a and 6b to add a complicated circuit for generating negative power supply voltages. Therefore, there is a problem that the number of parts increases to increase an apparatus size and a cost.

In contrast, unlike Japanese Patent Application Laid-open No. Hei 02-87963, the gate drive circuit as disclosed in Japanese Patent Application Laid-open No. 2004-328413 (gate drive circuit as schematically illustrated in FIG. 7) does not require the negative power supplies 6a and 6b. Therefore, the gate drive circuit disclosed in Japanese Patent Application Laid-open No. 2004-328413 may be provided using a very simple structure because the emitter terminals of the NPN transistors included in the gate drive circuit are only connected to the source terminals of the N-channel MOS-FETs.

As described above, the motor terminal voltage detection circuits 5a and 5b for detecting the motor terminal voltages are provided in the electric power steering apparatus. The motor terminal voltages detected by the motor terminal voltage detection circuits 5a and 5b are input to, for example, a microcomputer (not shown) and used to control the motor and determine the abnormality of the apparatus.

In the circuit structure of the motor drive circuit illustrated in FIG. 7, the emitter terminal of the NPN transistor Q2a of the gate drive circuit 3a is connected to the source terminal of the N-channel MOS-FET 10a. As is apparent from FIG. 7, the source terminal of the N-channel MOS-FET 10a also serves as the output terminal of the H-bridge circuit 1, that is, also serves as a motor terminal.

The motor terminal voltage detection circuit 5a described above is used to detect the terminal voltage of the motor terminal. However, when the gate drive circuit 3a operates to turn on the NPN transistor Q2a, the gate current flows into the motor terminal voltage detection circuit 5a. As a result, the motor terminal voltage detected by the motor terminal voltage detection circuit 5a causes an error.

The detected motor terminal voltage is used to determine the abnormality of the apparatus and control the motor. Therefore, when the detected motor terminal voltage causes an error, there is a problem that the motor cannot be accurately controlled and the abnormality of the apparatus may be erroneously determined. Thus, when the gate drive circuit as described above is used for the electric power steering apparatus, the steering feeling of the electric power steering apparatus deteriorates and the marketability thereof degrades.

### SUMMARY OF THE INVENTION

The present invention has been made to solve the problems described above. An object of the present invention is to provide a gate drive circuit capable of reliably turning off totem-pole-connected N-channel MOS-FETs, particularly a high-potential side N-channel MOS-FET, without adding a complicated structure, while preventing a detection error of a motor terminal voltage.

A gate drive circuit for driving a power MOS-FET according to the present invention includes: a first switching element connected to a gate terminal of the power MOS-FET through a first resistor, for setting a gate potential of the power MOS-FET to a potential for turning on the power MOS-FET, based on a signal from a signal source; and a second switching element connected to the gate terminal of the power MOS-FET through a second resistor, for setting the gate potential of the power MOS-FET to a potential for turning off the power MOS-FET, based on the signal from the signal source, in which the first resistor has a resistance value set to a value larger than a resistance value of the second resistor.

Further, the second resistor may be a wiring resistor between the gate terminal of the power MOS-FET and the second switching element. Further, the gate drive circuit may be an IC.

The present invention produces an effect that a gate drive circuit may be provided, which is capable of turning off a power MOS-FET reliably without adding a complicated structure, while preventing a detection error of a motor terminal voltage.

### BRIEF DESCRIPTION OF THE DRAWINGS

In the accompanying drawings:

FIG. 1 is a circuit diagram illustrating a structure of a motor drive circuit including a gate drive circuit according to a first embodiment of the present invention;

FIGS. 2A and 2B are circuit diagrams illustrating a modified example of the motor drive circuit including the gate drive circuit according to the first embodiment of the present invention;

FIG. 3 is a circuit diagram illustrating a modified example of the motor drive circuit including the gate drive circuit according to the first embodiment of the present invention;

FIG. 4 is a circuit diagram illustrating a structure of a motor drive circuit including a conventional gate drive circuit;

FIG. 5 is an explanatory diagram illustrating a switching operation of an N-channel MOS-FET;

FIG. 6 is a circuit diagram illustrating a structure of a motor drive circuit including a conventional gate drive circuit; and

FIG. 7 is a circuit diagram illustrating a structure of a motor drive circuit including a conventional gate drive circuit.

### DETAILED DESCRIPTION OF THE PREFERRED EMBODIMENT

Hereinafter, an embodiment of the present invention is described with reference to the attached drawings.

### First Embodiment

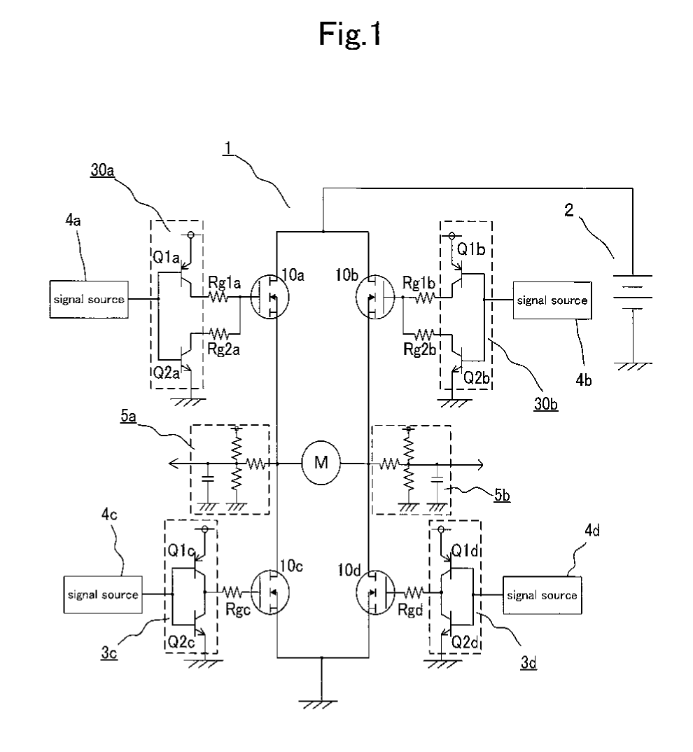

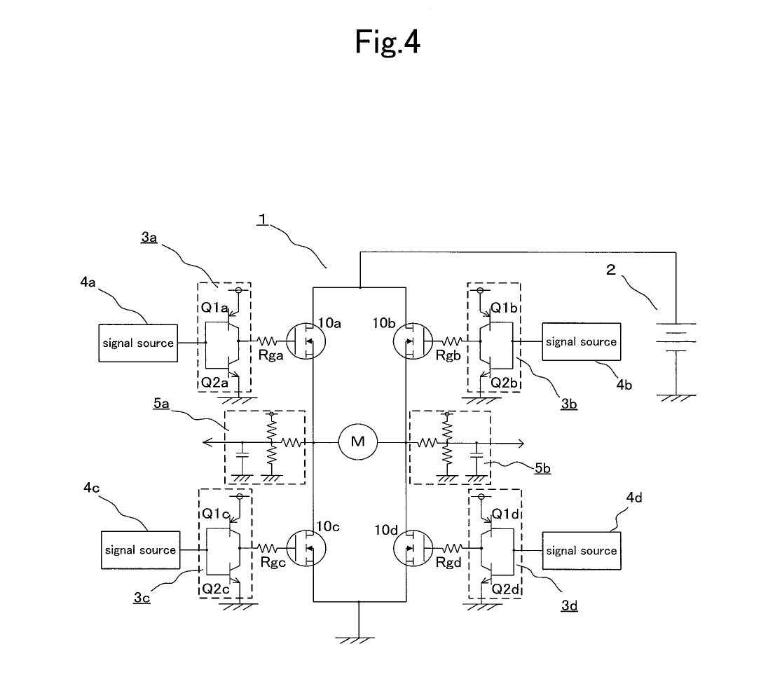

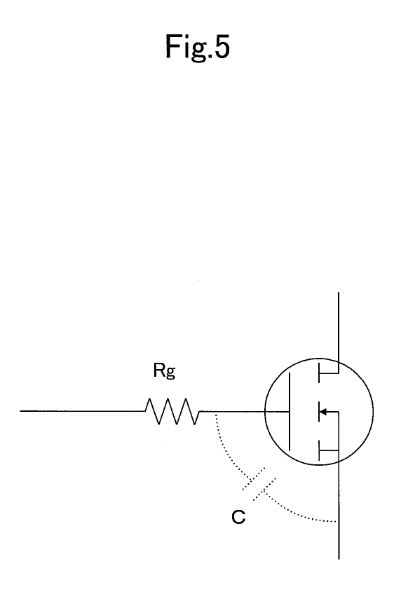

FIG. 1 is a circuit diagram illustrating a structure of a motor drive circuit including a gate drive circuit according to a first embodiment of the present invention. The circuit structure of the motor drive circuit illustrated in FIG. 1 is different from the circuit structure of the motor drive circuit illustrated in FIG. 4 in the point that two gate resistors Rg1a and Rg2a (Rg1b and Rg2b) are connected between a gate drive circuit 30a (30b) and a high-potential side N-channel MOS-FET 10a (10b) associated with the gate drive circuit 30a (30b). Resistance values of the gate resistors are set in advance to satisfy “Rg1a (=Rg1b)>Rg2a (=Rg2b)”.

In the motor drive circuit including the gate drive circuit illustrated in FIG. 1, the gate drive circuit 30a applies a signal to a gate terminal of the high-potential side N-channel MOS-FET 10a. A PNP transistor Q1a (first switching element) connected to a drive power supply (not shown) is turned on to apply the voltage from the drive power supply to the high-potential side N-channel MOS-FET 10a through the gate resistor Rg1a (first resistor). That is, in the gate drive circuit 30a, a gate potential of the high-potential side N-channel MOS-FET 10a is set to a potential for turning on the high-potential side N-channel MOS-FET 10a. Therefore, the gate drive circuit 30a turns on the high-potential side N-channel MOS-FET 10a.

In the gate drive circuit 30a, an NPN transistor Q2a (second switching element) is turned on to connect the gate terminal to a ground side of the drive power supply through the gate resistor Rg2a (second resistor). That is, in the gate drive circuit 30a, the gate potential of the high-potential side N-channel MOS-FET 10a is set to a potential for turning off the high-potential side N-channel MOS-FET 10a (ground potential). Therefore, the gate drive circuit 30a eliminates a gate-source potential difference of the high-potential side N-channel MOS-FET 10a to turn off the high-potential side N-channel MOS-FET 10a. The gate drive circuit 30b operates as in the gate drive circuit 30a.

As described above, the gate resistance values are set in advance to satisfy “Rg1a>Rg2a”. Therefore, a time constant of an integrating circuit including an input capacitor C of the N-channel MOS-FET and the gate resistor Rg1a or Rg2a is changed between the turn-on and -off operations of the high-potential side N-channel MOS-FET. As a result, a switching speed in the turn-off operation is higher than a switching speed in the turn-on operation.

Thus, when the N-channel MOS-FET 10a is turned off, the gate terminal of the N-channel MOS-FET 10a is connected to the ground side of the drive power supply through the gate resistor Rg2a and the NPN transistor Q2a. The resistance value of the gate resistor Rg2a is set to a value smaller than the resistance value of the gate resistor Rg1a as described above, and hence the switching speed is high. Therefore, the N-channel MOS-FET 10a may be rapidly and completely turned off. Even when the low-potential side N-channel MOS-FET 10c is turned on by a subsequent operation, there is no case where both the high-potential side N-channel MOS-FET 10a and the low-potential side N-channel MOS-FET 10c are turned on, and thus a short-circuit current does not flow.

In the gate drive circuit as described above, the resistance values of the gate resistors Rg1a and Rg2a are set to satisfy “Rg1a>Rg2a” so that the switching speed in the turn-off operation is higher than the switching speed in the turn-on operation. Therefore, electromagnetic noise occurring when the totem-pole-connected N-channel MOS-FETs are turned on may be suppressed.

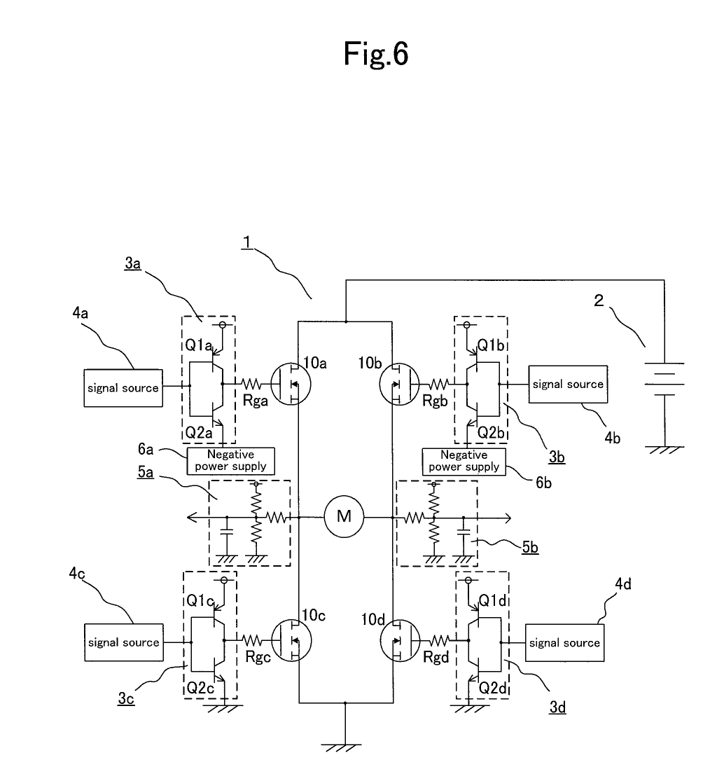

Unlike the conventional apparatus as illustrated in FIG. 6, it is unnecessary to provide the negative power supplies 6a and 6b. Therefore, even when a single power supply (vehicle-mounted battery in a case of electric power steering apparatus) is used as in the case of the electric power steering apparatus for vehicle, it is unnecessary to add a complicated circuit for generating negative power supply voltages. Therefore, increases in the number of parts, apparatus size, and cost do not occur.

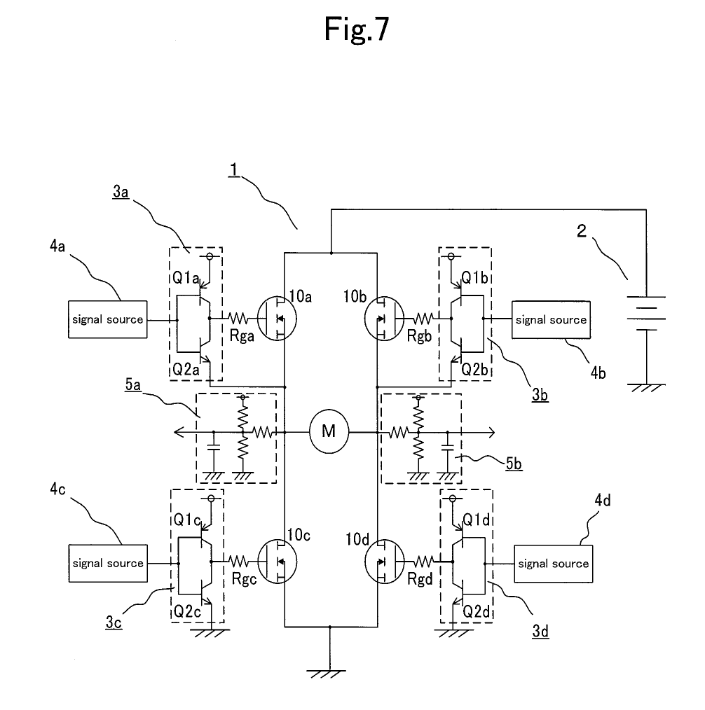

Unlike the conventional apparatus illustrated in FIG. 7, the structure is not employed in which the emitter terminal of the NPN transistor of the gate drive circuit is connected to the source terminal of the high-potential side N-channel MOS-FET. Therefore, the gate current does not flow into the motor terminal voltage detection circuit, and hence the detected motor terminal voltage does not cause an error. Thus, even when the gate drive circuit is used for the electric power steering apparatus, the deterioration of the steering feeling of the electric power steering apparatus and the degradation of the marketability thereof are not caused by the error.

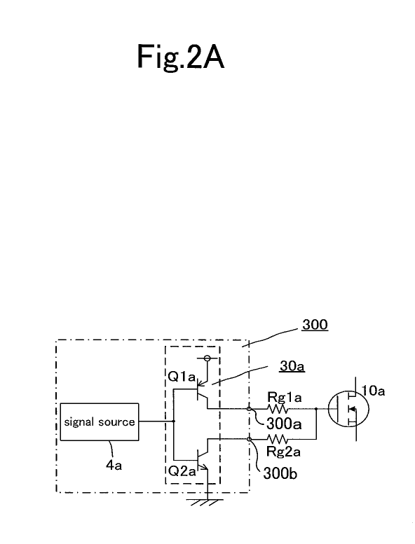

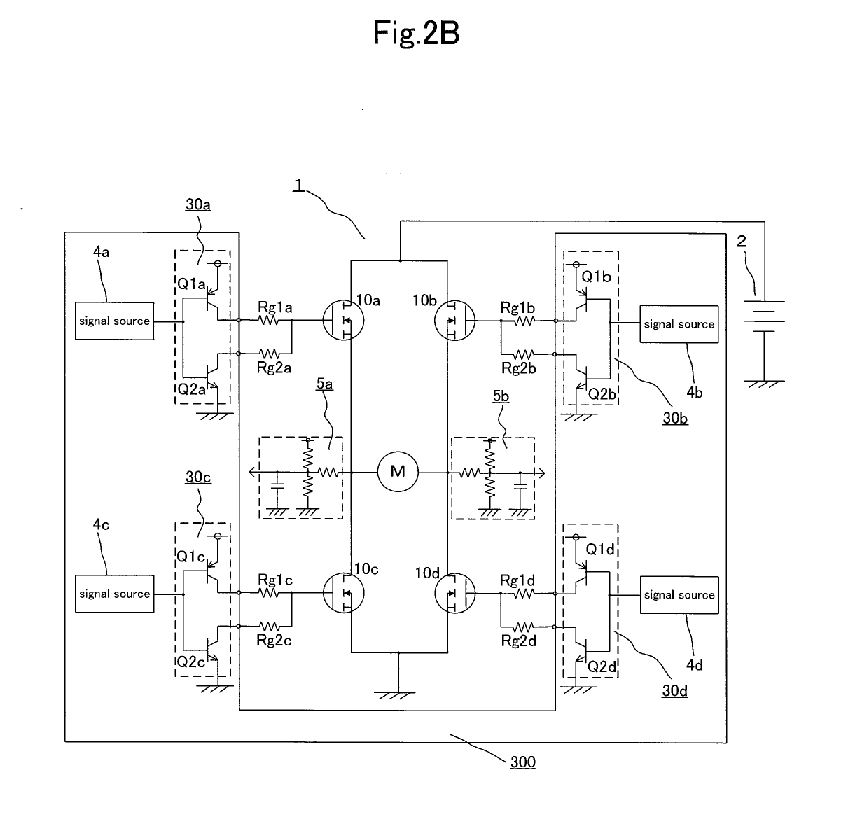

In the motor drive circuit including the gate drive circuit according to the first embodiment of the present invention described above, the gate drive circuit may have the discrete structure. Alternatively, as illustrated in FIG. 2A, the gate drive circuit may have a single structure of an integrated circuit (IC) 300 including the signal source. That is, an IC including two ports may be provided for each N-channel MOS-FET. The two ports of the IC correspond to a first port 300a for connecting the first resistor to the first switching element and a second port 300b for connecting the second resistor to the second switching element.

When the structure as illustrated in FIG. 2A is employed, a suitable switching speed may be obtained only by changing the gate resistors without an increase in IC chip size. In addition, the entire apparatus may be reduced in size and the degree of freedom of design may be improved.

FIG. 2A illustrates the structure of the IC 300 including only the signal source and the gate drive circuit for driving the single power MOS-FET. In contrast, as illustrated in FIG. 2B, the single IC 300 may include the signal sources 4a, 4b, 4c, and 4d and the gate drive circuits 30a, 30b, 30c, and 30d for driving all the power MOS-FETs 10a, 10b, 10c, and 10d provided in the H-bridge circuit.

FIG. 2B illustrates the example of the motor drive circuit having the H-bridge circuit structure, and hence the four signal sources and the four gate drive circuits are provided. However, in a case of a three-phase bridge circuit, six signal sources and six gate drive circuits are provided obviously. In other words, it is essential that the single IC be provided so that the number of driven power MOS-FETs is equal to each of the number of signal sources and the number of gate drive circuits. Therefore, when one kind of IC is prepared for each of the H-bridge circuit and the three-phase bridge circuit, which are generally used, the switching speed may be suitably adjusted by only changing the gate resistors, and hence standardization and a reduction in the number of parts may be realized.

In order to drive two power MOS-FETs which are totem-pole-connected, the single IC may include two signal sources and two gate drive circuits. In this case, even when the number of phases of the motor drive circuit is changed, the same IC may be used, and hence more advanced standardization may be realized though the number of parts somewhat increases.

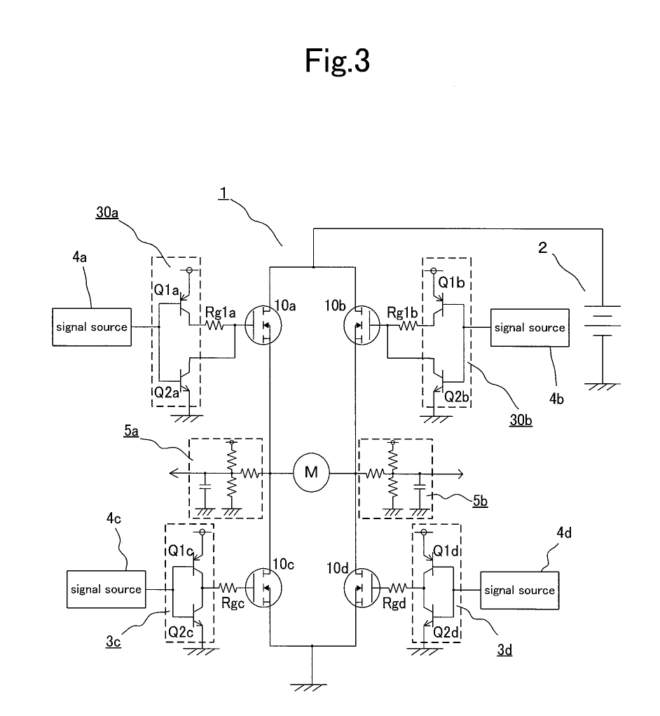

In the motor drive circuit including the gate drive circuit according to the first embodiment of the present invention described above, the gate resistor is provided on each of the turn-on side and the turn-off side. However, as illustrated in FIG. 3, no gate resistor may be provided on the turn-off side, and the gate terminal of the N-channel MOS-FET may be directly connected to the collector terminal of the NPN transistor of the gate drive circuit. That is, the gate resistor (corresponding to Rg2a of FIG. 1) provided on the turn-off side may be a simple wiring resistor between the gate terminal of the N-channel MOS-FET and the collector terminal of the NPN transistor. When such a structure is employed, the number of parts may be further reduced, the switching speed in the turn-off operation may be further increased, and a switching loss in the turn-off operation may be further reduced.

In the motor drive circuit including the gate drive circuit according to the first embodiment of the present invention described above, the gate drive circuit includes the PNP transistor and the NPN transistor. However, the present invention is not limited to this. An inverting circuit (inverter) may be provided at an input stage of one of two transistors having the same type. The gate drive circuit may include other switching elements such as FETs.

In the motor drive circuit including the gate drive circuit according to the first embodiment of the present invention described above, only the gate drive circuit for driving the high-potential side N-channel MOS-FET is connected to the high-potential side N-channel MOS-FET through the gate resistors provided on the turn-on side and the turn-off side. However, it should be understood that the gate drive circuit for driving the low-potential side N-channel MOS-FET may have the same structure as the gate drive circuit for driving the high-potential side N-channel MOS-FET.

In the motor drive circuit including the gate drive circuit according to the first embodiment of the present invention described above, the H-bridge circuit is used for the electrical load drive circuit. However, the present invention may be applied to any of so-called totem-pole type electrical load drive circuits such as a half-bridge circuit and a multi-phase bridge circuit as well as the H-bridge circuit as in the case of the H-bridge circuit.

1. A gate drive circuit for driving a power MOS-FET, comprising:
a first switching element connected to a gate terminal of the power MOS-FET through a first resistor, for setting a potential of the gate terminal of the power MOS-FET to a potential for turning on the power MOS-FET, based on a signal from a signal source; and
a second switching element connected to the gate terminal of the power MOS-FET through a second resistor, for setting the potential of the gate terminal of the power MOS-FET to a potential for turning off the power MOS-FET, based on the signal from the signal source,
wherein the first resistor has a resistance value set to a value larger than a resistance value of the second resistor.

2. A gate drive circuit according to claim 1, wherein the second resistor comprises a wiring resistor between the gate terminal of the power MOS-FET and the second switching element.

3. A gate drive circuit according to claim 1, wherein:
the gate drive circuit is an IC; and
the IC includes:
a first port for connecting the first resistor to the first switching element; and
a second port for connecting the second resistor to the second switching element.

4. A gate drive circuit according to claim 3, wherein the IC includes the two first switching elements and the two second switching elements.

5. A gate drive circuit according to claim 3, wherein the IC includes the same number of the first switching elements as the number of the driven power MOS-FETs, and the same number of the second switching elements as the number of the driven power MOS-FETs.
